(19) United States
(12) Patent Application Publication
(10) Pub. No.: US 2011/0048522 A1
(43) Pub. Date: Mar. 3, 2011

(54) SOLAR CELL

(75) Inventors: Chia-Chih Chuang, Miaoli County (TW); Jhe-Wei Guo, Yunlin County (TW); Tung-Po Hsieh, Taipei (TW)

(73) Assignee: INDUSTRIAL TECHNOLOGY RESEARCH INSTITUTE, Hsinchu County (TW)

(21) Appl. No.: 12/610,370

(22) Filed: Nov. 2, 2009

(30) Foreign Application Priority Data
Aug. 26, 2009 (TW) 098128647

(51) Int. Cl. H01L 31/00

(52) U.S. Cl. 136/256

(57) ABSTRACT

The invention provides a solar cell. The solar cell has the following structures: a substrate; a first electrode formed on the substrate; a light absorbing layer formed on the first electrode, wherein the light absorbing layer includes a first compound thin film and a second compound thin film, and a band gap of the second compound thin film is larger than that of the first compound thin film; a buffer layer formed on the light absorbing layer; a transparent conducting layer formed on the buffer layer; and a second electrode formed on the transparent conducting layer.

### CROSS REFERENCE TO RELATED APPLICATIONS

This Application claims priority of Taiwan Patent Application No. 098128647, filed on Aug. 26, 2009, the entirety of which is incorporated by reference herein.

### BACKGROUND OF THE INVENTION

1. Field of the Invention

The present invention relates to a solar cell, and in particular relates to a solar cell with a light absorbing layer comprising a double compound thin film.

2. Description of the Related Art

Technological development in the solar cell industry is driven by global environmental concerns and raw material prices. Among the various solar cells developed, CIGS thin film solar cells have become the subject of considerable interest due to advantages of high conversion efficiency, high stability, low cost, and large area fabrication.

A group IB-IIIA-VIA compound (also called CIGS compound) is a direct band gap semiconductor material that is used as a light absorbing layer of a CIGS solar cell. By changing the element ratios of the CIGS compound, the band gap of the semiconductor material can be regulated.

The band gap of the CIGS compound is about 1.0-1.68 eV. A higher open circuit voltage (V_{oc}) of the CIGS solar cell is obtained by increasing the band gap of the CIGS compound. However, as the band gap of the CIGS compound is increased, the short circuit current (J_{sc}) of the CIGS solar cell will decrease due to the decrease of the light absorbing wavelength of the light absorbing layer.

US patent discloses a method for fabricating a CIGS solar cell. A stacked precursor film comprising a copper-gallium alloy is formed and then a light absorbing layer is formed thereon by heating the precursor under an atmosphere containing sulfur or selenium vapor. The performance of the light absorbing layer is regulated by changing the concentration of the gallium elements to obtain a high open-circuit voltage of the CIGS solar cell.

Accordingly, there is a need to develop a CIGS solar cell having a high photoelectric conversion efficiency with high open circuit voltage (V_{oc}) and high short circuit current (J_{sc}).

### BRIEF SUMMARY OF THE INVENTION

The present invention provides a solar cell, comprising: a substrate; a first electrode formed on the substrate; a light absorbing layer formed on the first electrode, wherein the light absorbing layer comprises a first compound thin film and a second compound thin film and a band gap of the second compound thin film is larger than that of the first compound thin film; a buffer layer formed on the light absorbing layer; a transparent conducting layer formed on the buffer layer; and a second electrode formed on the transparent conducting layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a cross sectional schematic representation of a solar cell in accordance with embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

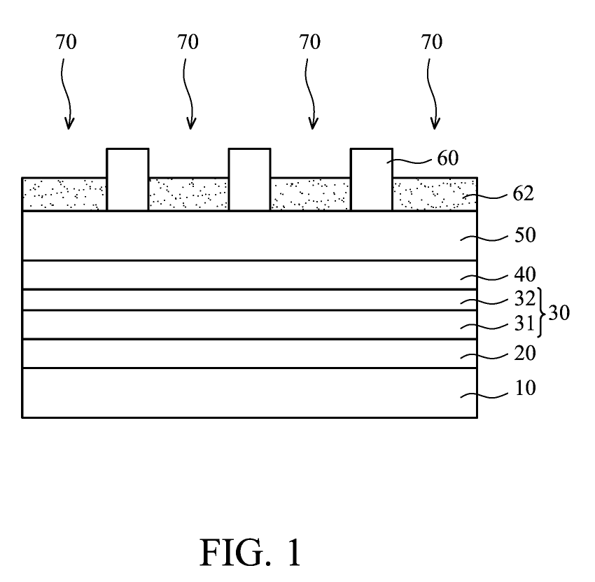

The invention provides a solar cell as shown in FIG. 1. The solar cell comprises a substrate 10, a first electrode 20, a light absorbing layer 30, a buffer layer 40, a transparent conducting layer 50 and a second electrode 60, wherein the light absorbing layer comprises a first compound thin film 31 and a second compound thin film 32, and a band gap of the second compound thin film 32 is larger than the first compound thin film 31. Thus, the wide band gap of the light absorbing layer is obtained by adjusting the ratio of the first compound thin film and the second compound thin film.

The invention also provides a fabrication method of a solar cell. Firstly, a substrate 10 is provided, wherein the substrate 10 comprises a glass, polymer, metal or combinations thereof. The polymer substrate is such as polyimide (PI), poly(ethylene terephthalate) (PET), poly carbonate (PC) or poly(methyl methacrylate) (PMMA).

Then, the first electrode 20 is formed on the substrate 10, wherein the first electrode 20 comprises Mo, Ti, W, Ta, Nb or combinations thereof. The first electrode 20 has a thickness of about 400 nm-1200 nm.

Next, the light absorbing layer 30 is formed on the first electrode 20, wherein the light absorbing layer 30 comprises the first compound thin film 31 and the second compound thin film 32. The first compound thin film 31 comprises CuₓIn_{y}Se₂, CuₓIn_{y}S₂, CuₓIn_{y}Ga_{1-y}Se₂ or CuₓIn_{y}Ga_{1-y}S₂, wherein x is between 0 and 1 and y is between 0 and 1, which is formed by a sputtering, evaporation, electroplating or multi-element evaporation process or processes.

The second compound thin film 32 comprises CuₓIn_{y}(Se_{z}S_{1-z})₂, CuₓIn_{y}Al_{1-y}S₂, CuₓIn_{y}Al_{1-y}Se₂, CuₓIn_{y}Ga_{1-y}(Se_{z}S_{1-z})₂ or CuₓIn_{y}Al_{1-y}(Se_{z}S_{1-z})₂, wherein x is between 0 and 1, y is between 0 and 1 and z is between 0 and 0.5. The second compound thin film 32 is formed by a rapid thermal process. The rapid thermal process is conducted in an atmosphere comprising H₂Se, H₂S, Se, S or combinations thereof, at a temperature of 400° C.-600° C., and a temperature ramp up rate of 1° C./s-5° C./s.

The first compound thin film 31 is thicker than the second compound thin film 32. The thickness of the first compound thin film is about 200 nm or larger, or preferably 600 nm-1500 nm or larger, or even further preferably 800 nm-1200 nm or larger. The thickness of the second compound thin film 32 is about 100 nm or larger, or preferably 200 nm-1000 nm or larger, or even further preferably 400 nm-800 nm or larger.

Note that in prior art the light absorbing layer comprises only one single compound thin film, thus it only has a single band gap. The light absorbing layer of the invention comprises double layers to increase the band gap therewithin. The band gap of the second compound thin film 32 is larger than that of the first compound thin film 31. In other words, the wide band gap of the second compound thin film 32 is formed on the narrow band gap of the first compound thin film 31. Therefore, the light absorbing layer 30 not only has the wide and narrow band gap but also maintains a high photocurrent.

Further, before the rapid thermal process, the forming of the second compound thin film further comprises forming aluminum or sodium-containing aluminum on the first compound thin film 31 by a sputtering, evaporation or electroplating process. The purpose of this step is to provide the aluminum element or sodium-containing aluminum to the second compound thin film. Therefore, the second compound thin film 32 comprises at least one more element than the first compound thin film 31 by the rapid thermal process. Additional elements may be elements such as sulfur (S), selenium (Se), aluminum (Al), sodium-containing aluminum or combinations thereof. Note that aluminum (Al) belongs to the Group III element (like indium (In) or gallium (Ga)), thus the electrical and physical property thereof is like that of the indium (In) or gallium (Ga), but the advantage is that fabrication costs thereof is lower than the indium (In) or gallium (Ga). When the sodium-containing aluminum is formed, the sodium will enter into the first compound thin film 31 and the second compound thin film 32 to facilitate the formation of light absorbing layer 30 crystals, thus the performance of the light absorbing layer 30 is improved.

In one embodiment, the first compound thin film 31 is CuInSe₂, and the second compound thin film 32 is CuIn(SeS)₂. In another embodiment, the first compound thin film 31 is CuInGaSe₂, and the second compound thin film 32 is CuInGa(SeS)₂. In yet another embodiment, the first compound thin film 31 is CuInSe₂, and the second compound thin film is CuInAlSe₂.

Then, the buffer layer 40 is formed on the light absorbing layer 30. The buffer layer 40 comprises CdS, ZnS, In₂S₃, ZnMgO, ZnO, In(OH)₃, Zn(OH)₂, InₓSe_{y} or combinations thereof and has a thickness of about 20 nm-200 nm. A hetero-junction diode is formed by using the buffer layer 40 as an n-type layer, and the light absorbing layer 30 as a p-type layer.

Next, the transparent conducting layer 50 is formed on the buffer layer 40. The transparent conducting layer 50 comprises ZnO:Al, In₂O₃:Sn, SnO₂:F or combinations thereof and has a thickness of about 200 nm-2000 nm.

The second electrode 60 is formed on the transparent conducting layer 50. The second electrode 60 comprises Al, Cu, Ni or combinations thereof and has a thickness of about 100 nm-3000 nm.

Further, an anti-reflection layer 62 is formed on the transparent conducting layer 50 in order to minimize the light 70 loss through reflection. The anti-reflection layer 62 comprises MgF₂ or other anti-reflection materials.

The light absorbing layer 30 of the solar cell of the invention comprises the first compound thin film 31 and second compound thin film 32 to increase the band gap therewithin. Therefore, the solar cell of the invention can have a high open circuit voltage (V_{oc}) and a high short circuit current (J_{sc}), simultaneously. Performance of the solar cell of the invention is as follows: a photoelectric conversion efficiency of about 7%-9%; an open-circuit voltage of about 0.3 V-0.54 V; a short-circuit current of about 35 mA/cm²-42 mA/cm²; and a fill factor of about 0.4-0.67.

The solar cell of the invention may be used as a portable power supply or a power supply of a building roof, a building curtain or a large electrical power generation plant.

### EXAMPLE

### Example 1

### Fabrication of the First Compound Thin Film

Firstly, a clean glass substrate is provided. Then, an Mo electrode is formed on the glass substrate by a physical evaporation process. Next, a 1200 nm of CuInSe₂ thin film is formed on the Mo electrode by a sputtering process while the temperature of the glass substrate is controlled at less then 200° C. After annealing at high temperatures, a CuInSe₂ thin film polycrystalline is obtained.

### Example 2

### Fabrication of the First Compound Thin Film

Firstly, a clean glass substrate is provided. Then, an Mo electrode is formed on the glass substrate by a physical evaporation process. Next, a CuInSe₂ thin film is formed on the Mo electrode by a sputtering process.

Then, a second CuGaSe₂ thin film is formed on the CuInSe₂ thin film by a second sputtering process while the temperature of the glass substrate is controlled at less then 200° C. to form a CuInSe₂/CuGaSe₂ stacked layer. The stacked layer has a total thickness of 1200 nm, wherein the thickness ratio of the CuInSe₂/CuGaSe₂ is 7/3. After annealing at high temperature, a CuInGaSe₂ thin film polycrystalline is obtained.

### Example 3

### Fabrication of the First Compound Thin Film

Firstly, a clean glass substrate is provided. Then, an Mo electrode is formed on the glass substrate by a physical evaporation process. Next, a CuInSe₂ thin film is formed on the Mo electrode by a multi-element evaporation process. During the multi-element evaporation process, the temperature of the glass substrate is controlled at about 400° C. to obtain a good thin film crystalline. Finally, a 2000 nm CuInSe₂ thin film is obtained.

### Example 4

### Fabrication of the First Compound Thin Film

Firstly, a clean glass substrate is provided. Then, an Mo electrode is formed on the glass substrate by a physical evaporation process. Next, a CuInGaSe₂ thin film is formed on the Mo electrode by a multi-element evaporation process. During the multi-element evaporation process, the temperature of the glass substrate is controlled at about 400° C. to obtain a good thin film crystalline. Finally, a 2000 nm CuInGaSe₂ thin film is obtained.

### Example 5

### Solar Cell

The glass/Mo/CuInSe₂ of Example 1 and 3 was put into a rapid thermal process chamber containing 0.2 g of sulfur powder. The temperature of the rapid thermal process chamber was raised to 550° C. from room temperature in 30 seconds with a temperature ramp up rate of 20° C./s. The chamber temperature was maintained at 550° C. for 90 seconds, and after 90 seconds the chamber was cooled down immediately. Thus, obtaining the CuInSe₂/CuIn(SeS)₂ double layer of the light absorbing layer.

Then, 50 nm of the CdS thin film was formed on the glass/Mo/CuInSe₂/CuIn(SeS)₂ by a chemical bath process. Next, a 50 nm/40 nm i-ZnO/ZnO:Al transparent electrode was formed on the CdS thin film by a sputtering process. Finally, a solar cell having a glass/Mo/CuInSe₂/CuIn(SeS)₂/CdS/i-ZnO/ZnO:Al structure was obtained for electrical measurement testing as shown in Table 1.

Table 1 shows the comparison of the performance of the single light absorbing layer formed without a rapid thermal process and the double light absorbing layer formed with a rapid thermal process of the invention. The data showed that the double light absorbing layer of the solar cell has higher photoelectric conversion efficiency.

TABLE 1

| | | Double layer: CuInSe₂/ |
|---|---|---|
| Light absorbing layer | Single layer: CuInSe₂ | CuIn(SeS)₂ |
| Open-circuit voltage | 0.32 | 0.37 |
| (V) | | |
| Fill factor | 0.54 | 0.56 |
| Short-circuit current | 38.2 | 40.6 |
| (mA/cm²) | | |
| Photoelectric | 6.7 | 8.3 |
| conversion | | |
| efficiency (%) | | |

### Example 6

### Solar Cell

The CuInSe₂ of Example 1 was firstly put into a sputtering chamber containing aluminum to form an aluminum thin film on the CuInSe₂ thin film and then put into a rapid thermal process chamber containing 0.2 g of selenium powder. The temperature of the rapid thermal process chamber was raised to 550° C. from room temperature in 30 seconds with a temperature ramp up rate of 20° C./5. The chamber temperature was maintained at 550° C. for 90 seconds, and after 90 seconds the chamber was cooled down immediately. Thus, obtaining a CuInSe₂/CuInAlSe₂ double layer of the light absorbing layer.

Then, 50 nm of the CdS thin film was formed on the glass/Mo/CuInSe₂/CuInAlSe₂ by a chemical bath plating process. Next, 50 nm/40 nm of i-ZnO/ZnO: Al transparent electrode was formed on the CdS thin film by a sputtering process. Finally, a solar cell having glass/Mo/CuInSe₂/CuInAlSe₂/CdS/i-ZnO/ZnO: Al structure was obtained for electrical measurement testing as shown in Table 2.

Table 2 shows the comparison of the performance of the single light absorbing layer formed without an Al thin film and the double light absorbing layer formed with an Al thin film of the invention. The data showed that the double light absorbing layer (with Al) of the solar cell had higher photoelectric conversion efficiency.

TABLE 2

| | Single layer | |
|---|---|---|
| | (w/o Al): | Double layer (with Al): |
| Light absorbing layer | CuInSe₂ | CuInSe₂/CuInAlSe₂ |
| Open-circuit voltage (V) | 0.32 | 0.36 |
| Fill factor | 0.59 | 0.61 |
| Short-circuit current | 34 | 37.9 |
| (mA/cm²) | | |
| Photoelectric conversion | 6.5 | 8.5 |
| efficiency (%) | | |

### Example 7

### Solar Cell

The CuInGaSe₂ of Example 4 was put into a rapid thermal process chamber containing 0.2 g of sulfur powder. The temperature of the rapid thermal process chamber was raised to 550° C. from room temperature in 30 seconds with a temperature ramp up rate of 20° C./s. The chamber temperature was maintained at 550° C. for 90 seconds, and after 90 seconds the chamber is cooled down immediately. Thus, obtaining a CuInGaSe₂/CuInGa(SeS)₂ double layer of the light absorbing layer.

Then, 50 nm of the CdS thin film was formed on the glass/Mo/CuInGaSe₂/CuInGa(SeS)₂ by a chemical bath plating process. Next, 50 nm/40 nm of i-ZnO/ZnO: Al transparent electrode was formed on the CdS thin film by a sputtering process. Finally, a solar cell having glass/Mo/CuInGaSe₂/CuInGa(SeS)₂/CdS/i-ZnO/ZnO: Al structure was obtained for electrical measurement testing as shown in Table 3.

Table 3 shows the comparison of the performance of the single light absorbing layer and the double light absorbing layer of the invention. The data showed that the double light absorbing layer of the solar cell had higher photoelectric conversion efficiency.

TABLE 3

| | Single layer: | Double layer: CuInGaSe₂/ |
|---|---|---|
| Light absorbing layer | CuInGaSe₂ | CuInGa(SeS)₂ |
| Open-circuit voltage (V) | 0.5 | 0.54 |
| Fill factor | 0.58 | 0.67 |
| Short-circuit current | 31.4 | 30.3 |
| (mA/cm²) | | |
| Photoelectric conversion | 9.1 | 10.9 |
| efficiency (%) | | |

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell, comprising:
a substrate;
a first electrode formed on the substrate;
a light absorbing layer formed on the first electrode, wherein the light absorbing layer comprises a first compound thin film and a second compound thin film, and a band gap of the second compound thin film is larger than that of the first compound thin film;
a buffer layer formed on the light absorbing layer;
a transparent conducting layer formed on the buffer layer; and
a second electrode formed on the transparent conducting layer.

2. The solar cell as claimed in claim 1, wherein the substrate comprises glass, polymer or metal.

3. The solar cell as claimed in claim 1, wherein the first electrode comprises Mo, Ti, W, Ta, Nb or combinations thereof.

4. The solar cell as claimed in claim 1, wherein the second compound thin film comprises at least one more element than the first compound thin film.

5. The solar cell as claimed in claim 1, wherein the first compound thin film comprises CuₓIn_{y}Se₂, CuₓIn_{y}S₂, CuₓIn_{y}Ga_{1-y}Se₂ or CuₓIn_{y}Ga_{1-y}S₂, wherein x is between 0 and 1 and y is between 0 and 1.

6. The solar cell as claimed in claim 1, wherein the second compound thin film comprises CuₓIn_{y}(Se_{z}S_{1-z})₂, CuₓIn_{y}Al_{1-y}S₂, CuₓIn_{y}Al_{1-y}Se₂, CuₓIn_{y}Ga_{1-y}(Se_{z}S_{1-z})₂ or CuₓIn_{y}Al_{1-y}(Se_{z}S_{1-z})₂, wherein x is between 0 and 1, y is between 0 and 1 and z is between 0 and 0.5.

7. The solar cell as claimed in claim 1, wherein the first compound thin film is thicker than the second compound thin film.

8. The solar cell as claimed in claim 1, wherein the first compound thin film has a thickness larger than about 200 nm.

9. The solar cell as claimed in claim 1, wherein the second compound thin film has a thickness larger than about 100 nm.

10. The solar cell as claimed in claim 1, wherein the buffer layer comprises CdS, ZnS, In₂S₃, ZnMgO, ZnO, In(OH)₃, Zn(OH)₂, InₓSe_{y} or combinations thereof.

11. The solar cell as claimed in claim 1, wherein the transparent conducting layer comprises ZnO:Al, In₂O₃:Sn, SnO₂:F or combinations thereof.

12. The solar cell as claimed in claim 1, wherein the second electrode comprises Al, Cu, Ni or combinations thereof.

13. The solar cell as claimed in claim 1, wherein the first compound thin film is formed by a sputtering, evaporation, electroplating or multi-element evaporation process.

14. The solar cell as claimed in claim 1, wherein the second compound thin film is formed by a rapid thermal process.

15. The solar cell as claimed in claim 14, wherein before performing the rapid thermal process, forming of the second compound thin film further comprises forming aluminum or sodium-containing aluminum on the first compound thin film by a sputtering, evaporation or electroplating process.

16. The solar cell as claimed in claim 14, wherein the rapid thermal process is conducted at a temperature of 400° C.-600° C.

17. The solar cell as claimed in claim 14, wherein the rapid thermal process is conducted at a temperature ramp up rate of 1° C./s-5° C./s.

18. The solar cell as claimed in claim 14, wherein the rapid thermal process is conducted in an atmosphere comprising H₂Se, H₂S, Se, S or combinations thereof.
